(19) United States
(12) Patent Application Publication
(10) Pub. No.: US 2012/0198780 A1
(43) Pub. Date: Aug. 9, 2012

(54) METHOD FOR ATTACHING A SOLAR MODULE TO A SUBSTRATE USING AN ADHESIVE

(75) Inventor: Paul Snowwhite, Dexter, MI (US)

(73) Assignee: ADCO Products, Inc., Michigan Center, MI (US)

(21) Appl. No.: 13/501,948

(22) PCT Filed: Oct. 14, 2010
(86) PCT No.: PCT/US10/52723

§ 371 Date: Apr. 13, 2012

Related U.S. Application Data
(60) Provisional application No. 61/251,559, filed on Oct. 14, 2009.

(51) Int. Cl. E04D 13/18; H01L 31/0216; B32B 37/12

(52) U.S. Cl. 52/173.3; 156/182; 136/256

(57) ABSTRACT

A method of attaching a solar module to a substrate includes first applying an adhesive to the substrate. The adhesive is preferably a liquid or hot melt adhesive or a pressure sensitive adhesive tape. Once the adhesive has been applied to the substrate, the solar module is placed in contact with the adhesive. Where the solar module is a flexible solar module, the solar module is preferably rolled onto the adhesive. Where the solar module is a rigid unit, the solar module is preferably first positioned above the adhesive and then pressed down into contact with the adhesive. The solar module is securely attached to the substrate upon curing of the adhesive.

### CROSS-REFERENCE TO RELATED APPLICATIONS

This application claims the benefit of U.S. Provisional Application No. 61/251,559, filed on Oct 14, 2009. The disclosure of the above application is incorporated herein by reference.

### FIELD

The present invention relates to a method for attaching a solar module to a substrate using an adhesive, wherein the adhesive includes double sided tapes and liquid adhesives.

### BACKGROUND

The statements in this section merely provide background information related to the present disclosure and may or may not constitute prior art.

Photovoltaic solar modules, building integrated photovoltaics (BIPV), solar mounting panels, solar thermal devices, thermoelectric solar modules, and other photovoltaic and light gathering devices, hereinafter referred to generally as “solar modules”, are regularly attached to roof decks and other substrates on buildings. These solar modules are directly affected by a variety of adverse weathering conditions including, but not limited to, wind, heat, cold, and water exposure. Accordingly, a method of securing a solar module to a substrate must be sufficiently adapted to meet weatherability and strength criteria, such as resistance to ultra-violet radiation exposure, freeze and thaw cycles, rain, snow, sleet, hail exposure, wind uplift forces, and extremes in temperature.

One common method of securing a solar module to a roofing substrate includes using a frame or rack to hold the solar module and using mechanical fasteners, such as screws or bolts, to secure the frame and the solar module to the roofing substrate. A wide variety of shapes, structures, and sizes have been proposed in the art to secure a solar module to a roofing substrate that meets the strength criteria while minimizing the difficulty and expense of installation. However, these frames and racks can be expensive and have difficulty in adapting to the shapes to the specific solar module or series of solar modules employed in a given application. In addition, mechanical fasteners penetrate the roofing substrate, which can lead to, for example, water invasion of a roof.

An alternate method of securing a component to a roofing substrate includes the use of chemicals or other agents applied to the back of the solar module. The solar module is then adhered to the roofing substrate using the chemicals or other agents. While effective, these chemicals or other agents that are packaged with the solar module may not be tailored to a given roof substrate. For example, the plasticizers in some roofing membranes can migrate into certain adhesives, resulting in the embrittlement and later cracking of the roofing membrane. In addition, these chemicals or other agents can increase the difficulty of storing and transporting the solar module.

Accordingly, there is a need in the art for a method of attaching a solar module to a substrate that uses an adhesive in order to maximize strength, weatherability, and ease of application, while simultaneously allowing a universal method of application that allows any solar module to be securely attached to any roofing substrate.

### SUMMARY

The present invention provides a method of attaching a solar module to a substrate. The method includes first applying an adhesive to the substrate. The adhesive is preferably a liquid or hot melt adhesive or a two-sided pressure sensitive adhesive tape. Once the adhesive has been applied to the substrate, the solar module is placed in contact with the adhesive. Where the solar module is a flexible solar module, the solar module is preferably rolled onto the adhesive. Where the solar module is a rigid unit, the solar module is preferably first positioned above the adhesive and then pressed down into contact with the adhesive. The solar module is securely attached to the substrate upon curing of the adhesive.

In another embodiment of the present invention, a method of attaching a solar module assembly to a substrate on a roof is provided. The method includes: obtaining a fully assembled solar module assembly, where the solar module assembly includes a front surface and a back surface; applying at least one discrete strip of adhesive to a top surface of the substrate; placing the back surface of the solar module on top of the at least one discrete strip of adhesive so that the front surface of the solar module is fully exposed; and pressing the back surface of the solar module assembly into the at least one discrete strip of adhesive.

In another example of the present invention, the method includes finishing attachment of the solar module assembly while a perimeter of the solar module assembly is fully exposed.

In yet another example of the present invention, the method includes curing the adhesive while a perimeter of the solar module assembly is fully exposed and where the at least one discrete strip of adhesive does not contact the front surface of the solar module assembly.

In yet another example of the present invention, applying at least one discrete strip of adhesive includes applying at least one continuous bead of adhesive using an applicator.

In yet another example of the present invention, applying at least one continuous bead of adhesive using an applicator includes applying a plurality of parallel continuous beads of adhesive using a plurality of applicator tips of a multi-bead applicator having a pump that mixes two separate components to create the adhesive.

In yet another example of the present invention, a distance between the plurality of parallel continuous beads is preselected to fully adhere the solar module assembly to the substrate.

In yet another example of the present invention, a distance between the plurality of parallel continuous beads is preselected to partially adhere the solar module assembly to the substrate with an adhesive to empty space ratio preselected based on expected environmental loads on the solar module assembly.

In yet another example of the present invention, applying at least one discrete strip of adhesive includes un rolling a self-wound adhesive tape onto the substrate, and removing a release liner to expose a surface on which the solar module will be placed.

In yet another example of the present invention, applying at least one discrete strip of adhesive includes applying a double sided pressure sensitive adhesive tape after removing a first release liner from the adhesive tape, and wherein placing the back surface of the solar module on top of the at least one discrete strip of adhesive includes placing the back surface of the solar module on top of the double sided pressure sensitive adhesive tape after removing a second release liner from the adhesive tape.

In yet another example of the present invention, the double sided pressure sensitive adhesive tape comprises at least one of one of polyurethane, ethylene-butylene-styrene, polyisobutene, polyisoprene, polybutenes,) styrene-butadiene-styrene (SBS), styrene-ethylene-butadiene-styrene (SEBS), styrene-isoprene-styrene (SIS), and acrylics comprising blends of methyl, ethyl, butyl, and 2-ethylthexyl acrylates and methyl, ethyl, butyl, and 2-ethylhexyl methacrylates.

In yet another example of the present invention, the solar module is a thin film solar module and placing the back surface of the solar module on top of the at least one discrete strip of adhesive includes unrolling a roll of the thin film solar module so that a backsheet of the thin film solar module contacts the at least one discrete strip of adhesive.

In yet another example of the present invention, applying at least one discrete strip of adhesive includes applying at least one discrete strip of adhesive to the roof on a perimeter of an expected location of the solar module on the roof.

In yet another example of the present invention, applying at least one discrete strip of adhesive includes applying at least one discrete strip of adhesive in an amount that is preselected based on expected environmental loads on the solar module assembly.

In yet another example of the present invention, the roof is one of ethylene propylene diene terpolymer (EPDM), thermoplastic olefin (TPO), polyvinyl chloride (PVC), styrene-butadiene-styrene (SBS) modified bitumen, atactic polypropylene (APP) modified bitumen, galvanized steel, aluminum, stainless steel, and painted steel that includes polyvinylidene fluoride (PVDF).

In yet another example of the present invention, the adhesive is one of a hot mop asphalt of type 1-4 with polymeric additives, a hot mop asphalt of type 1-4 without polymeric additives, pine tar pitch with polymeric additives, pine tar pitch without polymeric additives, ethylene vinyl acetate (EVA) copolymers compatible with paraffin, 1 k polyurethane, 1k silicone epoxy, 2 k polyurethane, styrene-isoprene-styrene (SIS) copolymers, styrene-butadiene-styrene (SBS) copolymers, ethylene ethyl acrylate copolymers (EEA), polyurethane reactive (PUR), butyl or halo-butyl rubbers, acrylic, ethylene propylene rubber (EPR), ethylene propylene diene terpolymer rubber (EPDM), styrene/butadiene rubbers (SBR), and styrene-ethylene-butene-styrene copolymers (SEBS).

In yet another example of the present invention, the solar module assembly includes a thin film solar module adhered to a fleece backed roofing membrane.

In yet another example of the present invention, the substrate is a flat rack attached to the roof.

Further areas of applicability will become apparent from the description provided herein. It should be understood that the description and specific examples and embodiments are intended for purposes of illustration only and are not intended to limit the scope of the present disclosure.

### DRAWINGS

FIG. 1 is an isometric view of an embodiment an exemplary substrate and an exemplary solar module attached according to the principles of the present invention;

FIG. 2 is a side cross-sectional view of the application of a liquid adhesive to the exemplary substrate according to the principles of the present invention;

FIG. 3 is a top view of the adhesive on the exemplary substrate according to the principles of the present invention;

FIG. 4 is a side cross-sectional view of an adhesive tape prior to application on the exemplary substrate according to the principles of the present invention;

FIG. 5 is a side cross-sectional view of the application of the adhesive tape to the exemplary substrate according to the principles of the present invention;

FIG. 6 is a side cross-sectional view of an exemplary flexible solar module being applied to the adhesive according to the principles of the present invention;

FIG. 7 is a top view of the exemplary flexible solar module being applied to the adhesive according to the principles of the present invention;

FIG. 8 is a side cross-sectional view of the exemplary flexible solar module fully applied to the adhesive according to the principles of the present invention;

FIG. 9 is a top view of the exemplary flexible solar module fully applied to the adhesive according to the principles of the present invention;

FIG. 10 is a side cross-sectional view of an exemplary rigid solar module being applied to the adhesive according to the principles of the present invention;

FIG. 11 is a side cross-sectional view of the exemplary rigid solar module fully applied to the adhesive according to the principles of the present invention; and

FIG. 12 is a side cross-sectional view of an exemplary solar pre-assembly being applied to a roofing substrate according to the principles of the present invention.

### DETAILED DESCRIPTION

The following description is merely exemplary in nature and is not intended to limit the present disclosure, application, or uses.

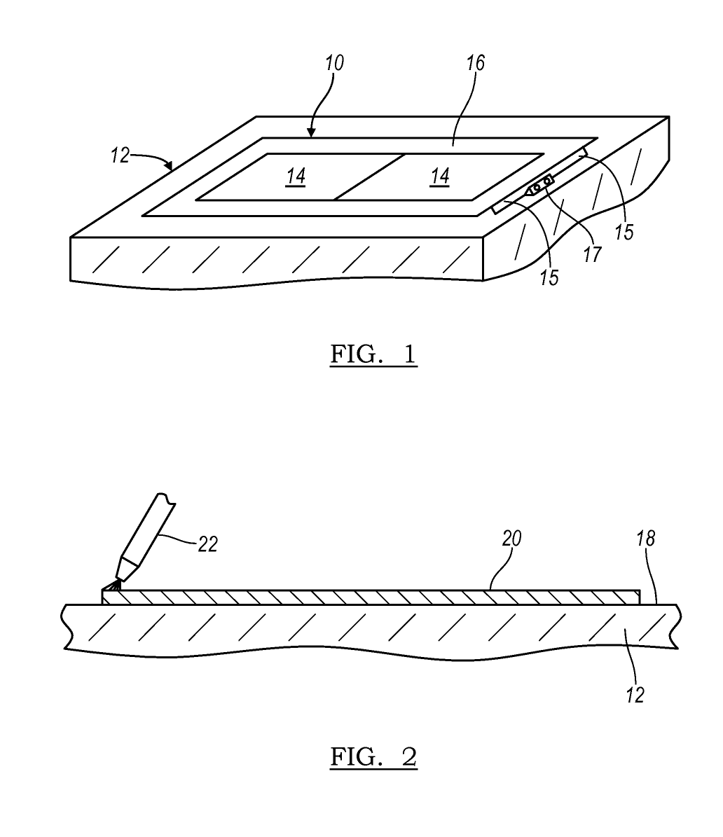

With reference to FIG. 1, a portion of an exemplary solar module 10 is illustrated secured to a portion of an exemplary substrate 12 according to the principles of the present invention. The solar module 10 generally includes one or more photovoltaic devices 14 linked in series or parallel that are operative to absorb light and generate a current in response to the absorption of the light. The current produced by the photovoltaic devices 14 are communicated via bus bars or other conductive materials or layers to wires or lead lines 15 that exit the solar module 10. The lead lines 15 communicate with a junction box 17 in order to distribute the electrical current generated by the solar module 10 to a power circuit.

The solar module 10 may be of various types and configurations, such as photovoltaic, thermoelectric, and hybrid without departing from the scope of the present invention. As used herein, the solar module 10 is an assembled solar device including a light gathering portion and a backside or backsheet portion. In the example embodiment provided, the solar module 10 is a flexible, thin film solar module having a flexible backsheet 16. The photovoltaic devices 14 are comprised of thin film cells with a layer of cadmium telluride (Cd—Te), amorphous silicon, or copper-indium-diselenide (CuInSe₂) or crystalline silicon wafers embedded in a laminating film or gallium arsenide deposited on germanium or another substrate. The photovoltaic devices 14 may be laminated or encapsulated such that they are adhered to the backsheet 16. Alternatively, the solar module 10 may be a rigid unit having wafer-based crystalline silicon with a rigid backsheet or rack. Again, it should be appreciated that the solar module 10 may be of any type or design without departing from the scope of the present invention.

The substrate 12 may take various forms without departing from the scope of the present invention. The substrate 10 is preferably a roof deck of a building, though other substrates may be employed without departing from the scope of the present invention. For example, in alternative embodiments the substrate 12 is a rack or flat aluminum tray and may be angled to maximize sun exposure. The substrate 10 may be comprised of various compositions, such as, for example, an ethylene propylene diene terpolymer (EPDM), a thermoplastic olefin (TPO), a polyvinyl chloride (PVC), a styrene-butadiene-styrene (SBS) modified bitumen, atactic polypropylene (APP) modified bitumen, galvanized steel, aluminum, stainless steel, and painted steel that includes polyvinylidene fluoride (PVDF), i.e. KYNAR™ coated steel. The substrate 10 includes an outer surface 18.

Turning to FIGS. 2-11, a method for attaching the solar module 10 to the substrate 12 will be described in further detail. First, an adhesive 20 is deposited onto the outer surface 18 of the substrate 12. In one embodiment of the present invention, as shown in FIG. 2, the adhesive 20 is a liquid or hot melt adhesive applied to the substrate 12 via an applicator 22. In the example provided, the applicator 22 is a dispensing tip of a multi-bead applicator having a pump for mixing the adhesive 20 and applying the adhesive 20 in beads. The applicator 22, however, may be a hot melt gun for hot melt adhesives or a mop, spray device, or other applicator for use with liquid adhesives without departing from the scope of the present invention. Examples of liquid or hot melt adhesives 20 suitable for use with the method include types 1-4 of hot mop asphalt with or without polymeric additives, pine tar pitches with or without polymeric additives, ethylene vinyl acetate (EVA) copolymers compatible with paraffin; 1 k polyurethane, 1 k silicone epoxy, 1 k moisture cure urethane, 1 k moisture cure silinated polyurethane, 1 k moisture cure MS polymer, and 2 k polyurethane; styrene-isoprene-styrene (SIS) copolymers; styrene-butadiene-styrene (SBS) copolymers; ethylene ethyl acrylate copolymers (EEA); and polyurethane reactive (PUR), butyl or halo-butyl rubbers, acrylic, ethylene propylene rubber (EPR), ethylene propylene diene terpolymer rubber (EPDM) or styrene/butadiene rubbers (SBR) and styrene-ethylene-butene-styrene copolymers (SEBS) including a variety of tackifying resins, and optionally waxes, antioxidants, plasticizers, and other materials added to the adhesive formulation to enhance the polymer performance. By way of a representative example only, a particular preferred pressure sensitive, hot melt adhesive is PSA-3 Hot Melt Adhesive commercially available from ADCO Products, Inc.

Examples of one-part polyurethanes are disclosed in U.S. Pat. No. 7,253,244 and the prior art cited therein. Examples of two-part polyurethanes are disclosed in U.S. Pat. No. 6,866,743 and the prior art cited therein.

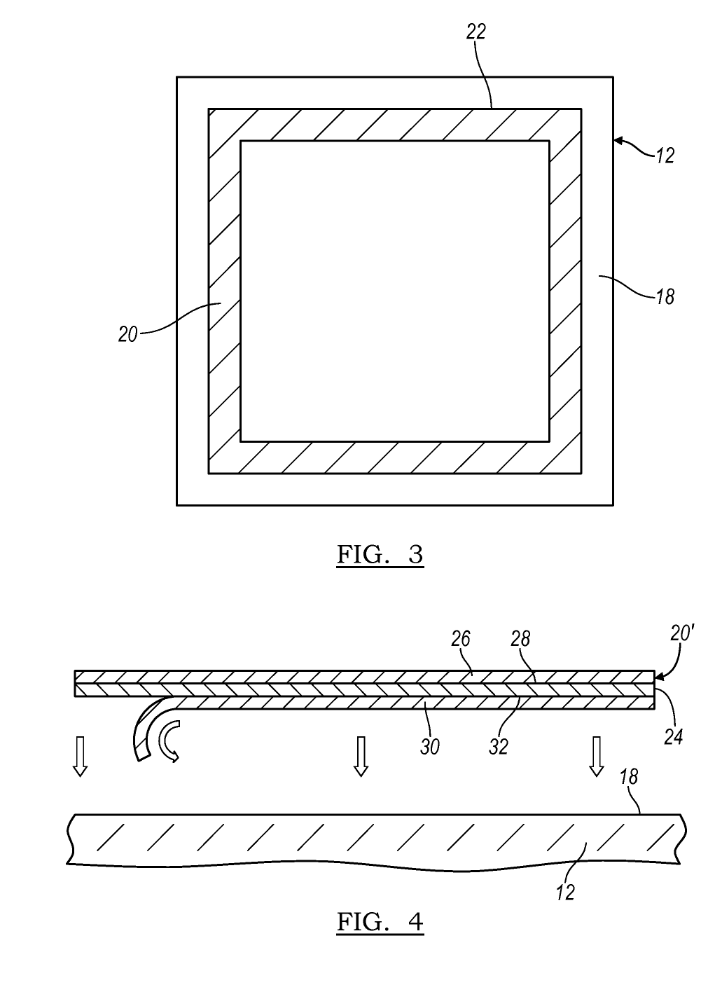

In a preferred embodiment, the adhesive 20 is applied in a continuous bead, as shown in FIG. 3, to form an outer perimeter 22 of adhesive 20 on the substrate 12. The outer perimeter 22 of the adhesive 20 is preferably sized such that the adhesive 20 will be located along an outer periphery of the solar module 10 when the solar module 10 is attached to the substrate 12, as will be described in greater detail below. Alternatively, the adhesive 20 may be applied in various other patterns and configurations on the outer surface 18 of the substrate 20, such as, for example, in crisscrossed or other diagonal patterns, in a continuous full sheet or layer, or in any other design. In one example, the multi-bead applicator applies multiple continuous beads of adhesive 20 simultaneously from multiple applicators 22 of a multi-bead applicator.

The patterns and the amount of the adhesive 20 to be applied are preferably selected to withstand the stresses associated with wind lift from fast moving air creating a low pressure above the solar module 10. A fully adhered solar module 10 includes a full layer of adhesive 20 between the solar module 10 and the substrate 12 with little to no air space, such as when beads of adhesive 20 are placed about three inches apart on the substrate 12 and are compressed together upon installing the solar module 10. A partially adhered solar module 10 would include a layer of adhesive 20 that includes at least some air space, such as when the compressed beads of adhesive 20 do not contact each other. The patterns and amount of adhesive 20 to be applied are preferably selected to balance loads on the adhesive 20 due to wind lift with ease of application and conservation of adhesive 20. In addition, the composition of the adhesive 20 should be considered when selecting the patterns and amount of adhesive 20 to apply. A partially adhered solar module 10 exerts a greater shear stress on the adhesive 20 than does a fully adhered solar module 10. Therefore, the shear properties of the adhesive 20 and/or the amount and patterns of the adhesive 20 are preferably selected to withstand the expected wind lift.

With reference to FIG. 4, an alternate adhesive suitable with the present invention is indicated by reference number 20′. The adhesive 20′ is preferably a two-sided pressure sensitive tape having an adhesive layer 24, a first release liner 26 disposed overtop a first side 28 of the adhesive layer 24, and a second release liner 30 disposed overtop a second side 32 of the adhesive layer 24. The release liners 26, 30 are operable to protect the adhesive layer 24 during transportation and handling of the adhesive 20′. Examples of adhesives 20′ suitable for use with the method include polyurethane, ethylene-butylene-styrene, and other known deal load shear capable adhesives such as PSA-3B Hot Melt Adhesive commercially available from ADCO Products, Inc. Other common pressure sensitive adhesives are based on ionomers and elastomers, such as butyl rubber based (containing polyisobutene and/or polyisoprene or polybutenes) or styrene block copolymers such as styrene-butadiene-styrene (SBS), styrene-ethylene-butadiene-styrene (SEBS), styrene-isoprene-styrene (SIS), and acrylics. Examples of acrylics include, but are not limited to, blends of methyl, ethyl, butyl, and 2-ethylthexyl acrylates and methyl, ethyl, butyl, and 2-ethylhexyl methacrylates.

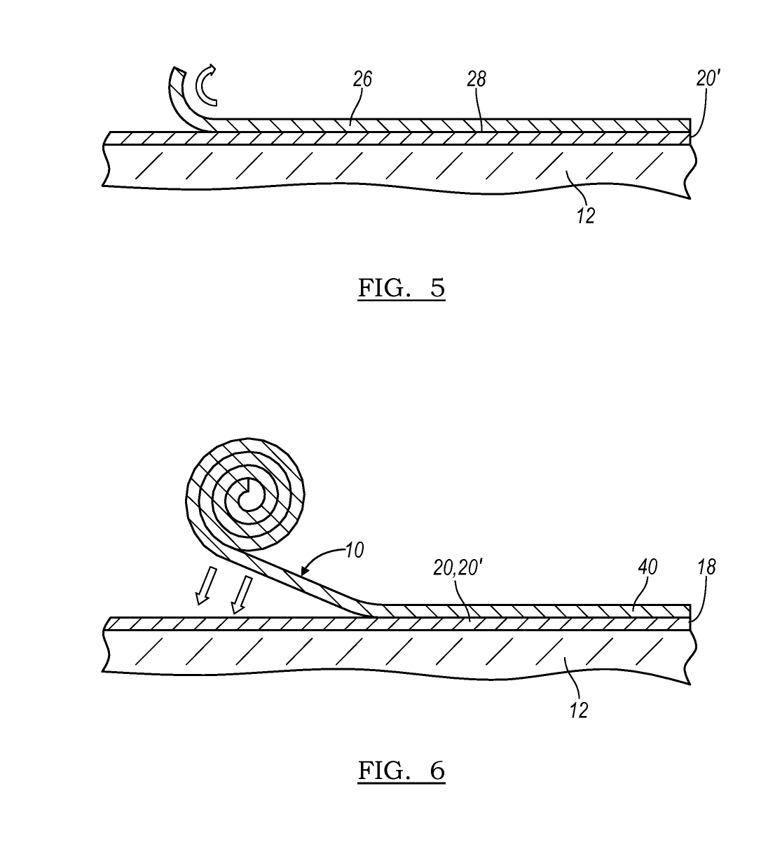

The adhesive 20′ is applied by first removing the second release liner 30 from the adhesive layer 24 thereby exposing the second side 32. Next, the adhesive 20′ is rolled down or otherwise pressed onto the outer surface 18 of the substrate 12. Next, as shown in FIG. 5, the first release liner is removed from the adhesive layer 24 thereby exposing the first side 28. The adhesive 20′ may be applied in a pattern similar to that shown in FIG. 3, or applied in any other configuration or pattern described above in regards to the adhesive 20.

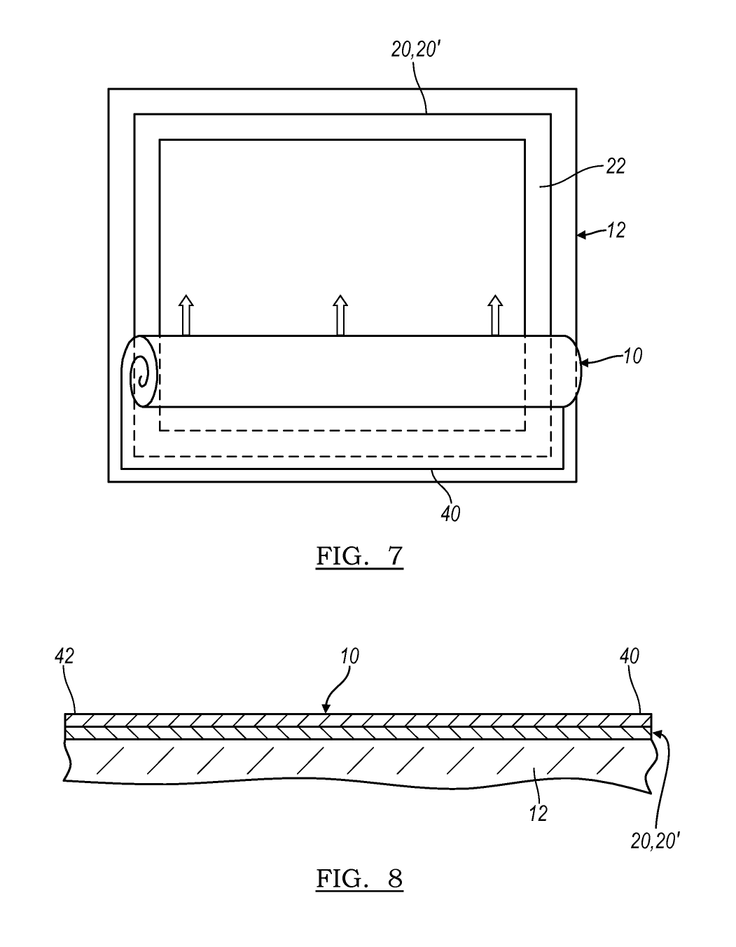

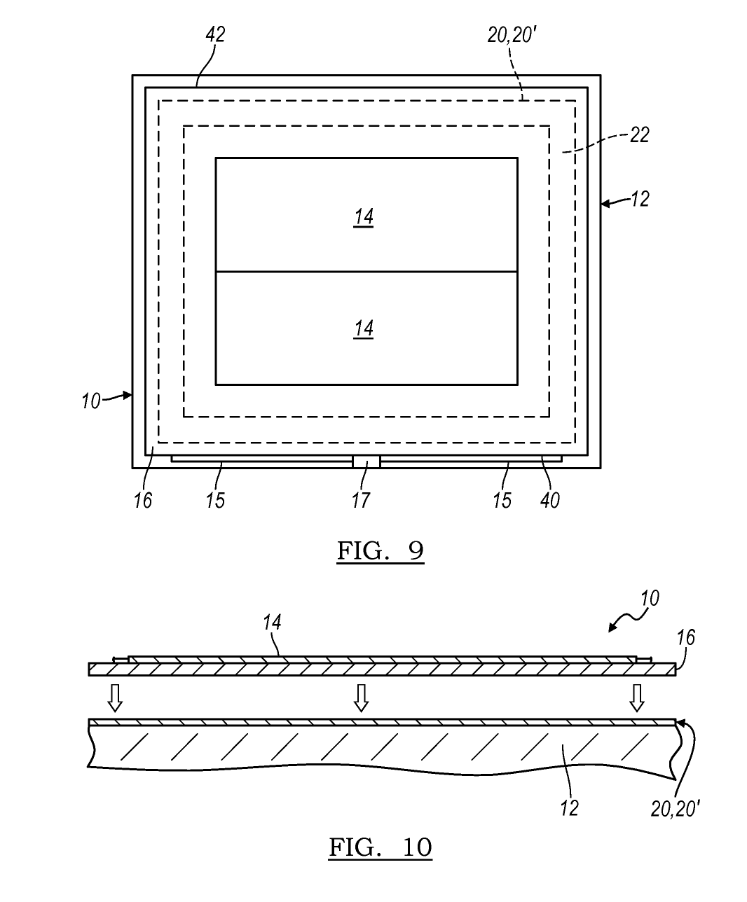

Once the adhesive 20, 20′ has been applied to the substrate 12, the solar module 10 is placed in contact with the adhesive 20, 20′. The adhesive 20, 20′ secures the solar module 10 to the substrate 12. For example, in an embodiment where the solar module 10 is a flexible solar module as shown in FIGS. 6-9, the solar module 10 is preferably pressed at a first end 40 thereof onto the adhesive 20, 20′. Next, the solar module 10 is rolled out in the direction of the arrows in FIGS. 6 and 7 onto the substrate 12. The solar module 10 is in place when a second end 42 of the solar module 10 is secured to the substrate 12, as shown in FIGS. 8 and 9. The solar module 10 is securely attached to the substrate 12 upon curing of the adhesive 20, 20′. Installation is completed by connecting the solar module 10 to an appropriate power grid. In a preferred embodiment, the solar module 10 is removable from the substrate 12 by cutting the backsheet 16 between the outer perimeter 22 of the adhesives 20, 20′ and the photovoltaic cells 14.

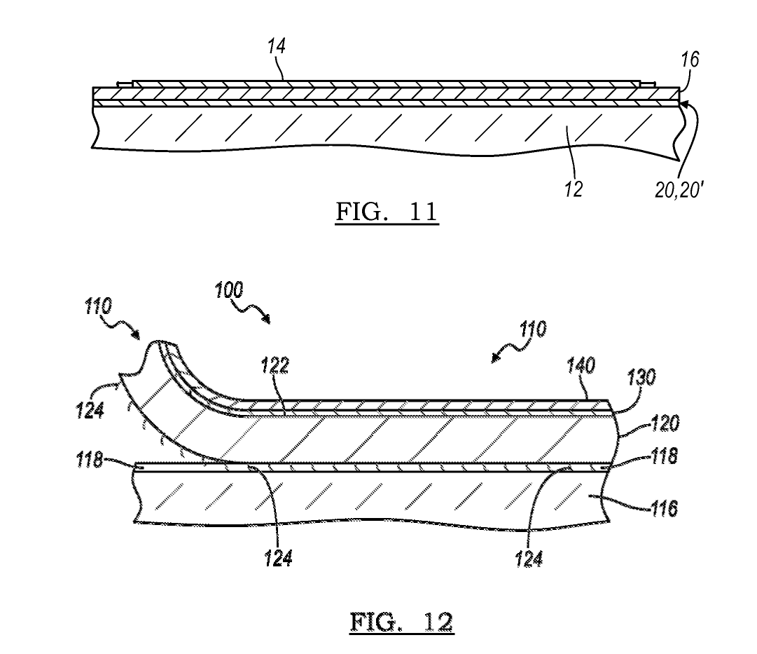

In an embodiment where the solar module 10 is a rigid solar module as shown in FIGS. 10 and 11, the solar module 10 is preferably first positioned overtop the adhesive 20, 20′. Next, the solar module 10 is pressed into place onto the adhesive 20, 20′ as a unit in the direction of the arrows in FIG. 10. The solar module 10 is securely attached to the substrate 12 upon curing of the adhesive 20, 20′. Installation is completed by connecting the solar module 10 to an appropriate power grid.

It should be appreciated that the specific type of adhesive 20, 20′ may be selected based on the type and material of the substrate 12 as well as the type and size of the solar module 10 used in a given application. Accordingly, the method of attachment of the solar module 10 to the substrate 12 assures ease and efficiency of application while maintaining properties after ageing as required by Underwriter's Laboratories and IEC regulations.

Turning now to FIG. 12, a solar pre-assembly 110 is illustrated being installed in a rooftop environment indicated by reference number 100. The assembly is illustrated being installed on an insulation or cover board 116 by a first adhesive layer 118. The insulation or cover board 116 is generally adhered to a roofing substrate, such as, for example, a concrete, light weight concrete, wood, gypsum, wood fiber or steel roof deck.

The solar pre-assembly 110 is generally fully assembled in a manufacturing facility, and may be known as a solar mat or building integrated photovoltaic. The solar pre-assembly 110 generally includes a fleece backed membrane 120, a second adhesive layer 130, and a solar module 140. The fleece backed membrane 120 includes an upper layer 122 and a fleece-like layer 124. The upper layer 120 is preferably a rubber like layer made from, for example, EPDM or TPO. The fleece-like layer 124 is secured to an underside of the upper layer 120. The fleece-like layer 124 is preferably a non-woven polyester fleece-like layer, though other fleece-like or fibrous materials may be used. Examples include Carlisle's FleeceBACK® EPDM and FleeceBACK® TPO. The fleece-like layer 124 at least partially penetrates the second adhesive layer 118 when installed on the insulation board 116, thereby providing a secure adhesive and mechanical bond between the second adhesive layer 118 and the fleece backed membrane 120.

The second adhesive layer 130 is disposed between the solar module 140 and the fleece backed membrane 120. The second adhesive layer 130 is similar to the adhesive 20, 20′ described above. The second adhesive layer 130 may be applied in the same manner and proportions as the adhesives 20, 20′, however the adhesive layer 130 is applied in a manufacturing facility rather than on an installation site such as a roof of a building. The solar module 140 is similar to the solar module 10 described above, however the solar module 140 is adhered to the top surface 122 of the fleece backed membrane 120 in a manufacturing facility.

With further reference to FIG. 12, installation of the solar pre-assembly 110 onto the insulation board 116 will now be described. The first adhesive layer 118 is applied to the insulation board 116. The first adhesive layer 118 at least partially penetrates the fleece-like layer 124 to adhere the fleece backed membrane 120 to the insulation board 116. The first adhesive layer 118 is a two-part adhesive composition generally formed by combining the two separate compositions or blends prior to application on the roofing substrate. The two parts include a “B Side” or resin side and an “A Side” or isocyanate containing side. Each of the sides are packaged separately and are mixed by an applicator prior to applying on the roofing substrate, such as by a multi-bead applicator or adhesive gun. Once the first adhesive layer 118 has been applied to the insulation board or cover board layer 116, the solar pre-assembly 110 is rolled or otherwise applied overtop the insulation board 116 so that the fleece like layer 124 of the fleece backed member 120 faces the adhesive layer 118. Because the solar module 140 is pre-assembled with the fleece backed membrane 120, no further layers of adherent are needed at the installation site.

The description of the invention is merely exemplary in nature and variations that do not depart from the gist of the invention are intended to be within the scope of the invention. Such variations are not to be regarded as a departure from the spirit and scope of the invention.

1. A method of attaching a solar module assembly to a substrate on a roof, the method comprising:
obtaining a fully assembled solar module assembly, wherein the solar module assembly includes a front surface and a back surface;
applying at least one discrete strip of adhesive to a top surface of the substrate;
placing the back surface of the solar module on top of the at least one discrete strip of adhesive so that the front surface of the solar module is fully exposed; and
pressing the back surface of the solar module assembly into the at least one discrete strip of adhesive.

2. The method of claim 1 further comprising finishing attachment of the solar module assembly while a perimeter of the solar module assembly is fully exposed.

3. The method of claim 1 further comprising curing the adhesive while a perimeter of the solar module assembly is fully exposed and wherein the at least one discrete strip of adhesive does not contact the front surface of the solar module assembly.

4. The method of claim 1 wherein applying at least one discrete strip of adhesive includes applying at least one continuous bead of adhesive using an applicator.

5. The method of claim 4 wherein applying at least one continuous bead of adhesive using an applicator includes applying a plurality of parallel continuous beads of adhesive using a plurality of applicator tips of a multi-bead applicator having a pump that mixes two separate components to create the adhesive.

6. The method of claim 5 wherein a distance between the plurality of parallel continuous beads is preselected to fully adhere the solar module assembly to the substrate.

7. The method of claim 5 wherein a distance between the plurality of parallel continuous beads is preselected to partially adhere the solar module assembly to the substrate with an adhesive to empty space ratio preselected based on expected environmental loads on the solar module assembly.

8. The method of claim 1 wherein applying at least one discrete strip of adhesive includes un rolling a self-wound adhesive tape onto the substrate, and removing a release liner to expose a surface on which the solar module will be placed.

9. The method of claim 1 wherein applying at least one discrete strip of adhesive includes applying a double sided pressure sensitive adhesive tape after removing a first release liner from the adhesive tape, and wherein placing the back surface of the solar module on top of the at least one discrete strip of adhesive includes placing the back surface of the solar module on top of the double sided pressure sensitive adhesive tape after removing a second release liner from the adhesive tape.

10. The method of claim 9 wherein the double sided pressure sensitive adhesive tape comprises at least one of one of polyurethane, ethylene-butylene-styrene, polyisobutene, polyisoprene, polybutenes,) styrene-butadiene-styrene (SBS), styrene-ethylene-butadiene-styrene (SEBS), styrene-isoprene-styrene (SIS), and acrylics comprising blends of methyl, ethyl, butyl, and 2-ethylthexyl acrylates and methyl, ethyl, butyl, and 2-ethylhexyl methacrylates.

11. The method of claim 1 wherein the solar module is a thin film solar module and placing the back surface of the solar module on top of the at least one discrete strip of adhesive includes unrolling a roll of the thin film solar module so that a backsheet of the thin film solar module contacts the at least one discrete strip of adhesive.

12. The method of claim 1 wherein applying at least one discrete strip of adhesive includes applying at least one discrete strip of adhesive to the roof on a perimeter of an expected location of the solar module on the roof.

13. The method of claim 1 wherein applying at least one discrete strip of adhesive includes applying at least one discrete strip of adhesive in an amount that is preselected based on expected environmental loads on the solar module assembly.

14. The method of claim 1 wherein the roof is one of ethylene propylene diene terpolymer (EPDM), thermoplastic olefin (TPO), polyvinyl chloride (PVC), styrene-butadiene-styrene (SBS) modified bitumen, atactic polypropylene (APP) modified bitumen, galvanized steel, aluminum, stainless steel, and painted steel that includes polyvinylidene fluoride (PVDF).

15. The method of claim 1 wherein the adhesive is one of a hot mop asphalt of type 1-4 with polymeric additives, a hot mop asphalt of type 1-4 without polymeric additives, pine tar pitch with polymeric additives, pine tar pitch without polymeric additives, ethylene vinyl acetate (EVA) copolymers compatible with paraffin, 1 k polyurethane, 1 k silicone epoxy, 2 k polyurethane, styrene-isoprene-sytrene (SIS) copolymers, styrene-butadiene-styrene (SBS) copolymers, ethylene ethyl acrylate copolymers (EEA), polyurethane reactive (PUR), butyl or halo-butyl rubbers, acrylic, ethylene propylene rubber (EPR), ethylene propylene diene terpolymer rubber (EPDM), styrene/butadiene rubbers (SBR), and styrene-ethylene-butene-styrene copolymers (SEBS).

16. The method of claim 1 wherein the solar module assembly includes a thin film solar module adhered to a fleece backed roofing membrane.

17. The method of claim 1 wherein the substrate is a flat rack attached to the roof.

18. A method of attaching a thin film solar module to a roof, the method comprising:
providing a roll of a fully assembled thin film solar module, wherein the thin film solar module includes a front surface and a back surface;
applying at least one discrete strip of adhesive to a top surface of the roof;
placing the back surface of a first end of the roll of the thin film solar module on top of the at least one discrete strip of adhesive;
unrolling the roll of the thin film solar module onto the at least one discrete strip of adhesive;
pressing the back surface of the thin film solar module into the at least one discrete strip of adhesive.

19. The method of claim 18 further comprising finishing attachment of the solar module while a perimeter of the thin film solar module is fully exposed.

20. The method of claim 18 wherein applying at least one discrete strip of adhesive includes applying at least one continuous bead of adhesive using an applicator.

21. The method of claim 20 wherein applying at least one continuous bead of adhesive using an applicator includes applying at least one continuous bead of adhesive using an applicator that mixes two separate components to create the adhesive.

22. The method of claim 18 wherein applying at least one discrete strip of adhesive includes applying a double sided pressure sensitive adhesive tape after removing a first release liner from the adhesive tape, and wherein placing the back surface of the solar module on top of the at least one discrete strip of adhesive includes placing the back surface of the solar module on top of the double sided pressure sensitive adhesive tape after removing a second release liner from the adhesive tape.

23. The method of claim 18 wherein applying the at least one discrete strip of adhesive includes unrolling a self-wound adhesive tape onto the substrate, and then removing a release liner to expose a surface on which the solar module will be placed.

24. The method of claim 18 wherein applying at least one discrete strip of adhesive includes applying at least one discrete strip of adhesive to the roof on a perimeter of an expected location of the solar module on the roof.

25. A method of attaching a solar module to a roof, the method comprising:
supplying a fully assembled solar module, wherein the solar module includes a front surface and a back surface;
providing a double sided pressure sensitive adhesive tape with a tape surface and a second tape surface having a release liner;
applying the first tape surface of the adhesive tape to the roof while the release liner is still on the second tape surface of the adhesive tape;
removing the second release liner from the second tape surface of the adhesive tape while the adhesive tape is on the roof;
placing the back surface of the solar module on top of the first surface of the adhesive tape so that the front surface of the solar module faces away from the roof; and
pressing the back surface of the solar module into the at least one discrete strip of adhesive.

26. A solar pre-assembly comprising:
a solar module;
a roofing membrane having a top side and a bottom side, wherein the bottom side includes a fleece layer having a plurality of fibrous materials; and
an adhesive layer disposed between and adhering the solar module to the top side of the roofing membrane.

27. The solar pre-assembly of claim 26 wherein the solar module is a thin film solar module.

28. The solar pre-assembly of claim 26 wherein the top side of the roofing membrane is made from one of EPDM and TPO.

29. The solar pre-assembly of claim 26 wherein the fleece layer is a non-woven polyester fleece type layer.

30. The solar pre-assembly of claim 26 wherein a ratio of adhesive to empty space in the adhesive layer is preselected based on a predetermined wind lift force.

31. The solar pre-assembly of claim 26 wherein the adhesive layer includes a hot melt adhesive.

32. An installed solar module assembly comprising:
an insulation board including a top side and a bottom side, wherein the bottom side is adhered to a substrate of a roof;
a roofing membrane having a top side and a bottom side, wherein the bottom side includes a fleece layer having a plurality of fibrous materials;
a urethane adhesive layer adhering the top side of the insulation board with the bottom side of the roofing membrane, wherein the urethane adhesive layer at least partially permeates the fleece layer of the bottom side of the roofing membrane;
a solar module; and
a second adhesive layer disposed between and adhering the solar module to the top side of the roofing membrane.

33. The installed solar module assembly of claim 32 wherein the solar module is a thin film solar module.

34. The installed solar module assembly of claim 32 wherein the top side of the roofing membrane is made from one of EPDM and TPO.

35. The installed solar module assembly of claim 32 wherein the fleece layer is a non-woven polyester fleece type layer.

36. The installed solar module assembly of claim 32 wherein a ratio of adhesive to empty space in the adhesive layer is preselected based on a predetermined wind lift force.

37. The installed solar module assembly of claim 32 wherein a period of time of curing for the second adhesive layer is longer than a period of time of curing for the urethane adhesive layer at a single point in time.

38. The installed solar module assembly of claim 32 wherein the urethane adhesive layer is a two part adhesive composition comprising a resin part and an isocyanate part.

39. The installed solar module assembly of claim 32 wherein the second adhesive layer includes a hot melt adhesive.
